(19) United States
(12) Patent Application Publication
(10) Pub. No.: US 2009/0028055 A1
(43) Pub. Date: Jan. 29, 2009

(54) CORRELATION-BASED LOCALIZATION OF PROBLEMS IN A VOIP SYSTEM

(76) Inventor: Olaf Carl Zaencker, Bad Oldesloe (DE)

Correspondence Address: HUGH P. GORTLER, 23 ARRIVO DRIVE, MISSION VIEJO, CA, 92692, US

(21) Appl. No.: 11/828,335

(22) Filed: Jul. 25, 2007

(51) Int. Cl. G01R 31/08

(52) U.S. Cl. 370/242

(57) ABSTRACT

Diagnostics data is accessed from VoIP-aware devices in an IP network. The diagnostics data indicates problems that cause degradation in VoIP voice quality. Correlations of a diagnosed problem are identified, and the correlations are used to localize a cause of the diagnosed problem.

### BACKGROUND

VoIP is an acronym for Voice over IP or, in more common terms, phone service over IP networks. VoIP offers certain advantages over plain old telephone service (POTS), such as lower cost and increased functionality.

However, VoIP still doesn't provide the same level of service and reliability as POTS. Quality of VoIP can be degraded by sender problems, network problems, and receiver problems.

Troubleshooting voice quality problems in an IP system (and on all VoIP) is complex because the system carries voice data on a converged network without explicit capability to support real-time traffic.

### BRIEF DESCRIPTION OF THE DRAWINGS

FIG. 1 is an illustration of a system in accordance with an embodiment of the present invention.

FIG. 2 is an illustration of a diagnostics data structure in accordance with an embodiment of the present invention.

FIG. 3 is an illustration of a method in accordance with an embodiment of the present invention.

FIG. 4 is a timeline of different VoIP audio streams.

FIG. 5 is an illustration of a method of identifying correlations and identifying a cause of a diagnosed problem in accordance with an embodiment of the present invention.

FIG. 6 is an illustration of a portion of an RTP packet.

FIG. 7 is an illustration of a method of generating artificial VoIP traffic in accordance with an embodiment of the present invention.

FIG. 8 is an illustration of a method of searching for the cause of a VoIP voice degradation problem by introducing artificial VoIP traffic in accordance with an embodiment of the present invention.

FIG. 9 is an illustration of a VoIP-aware device in accordance with an embodiment of the present invention.

FIG. 10 is an illustration of a management system in accordance with an embodiment of the present invention.

### DETAILED DESCRIPTION

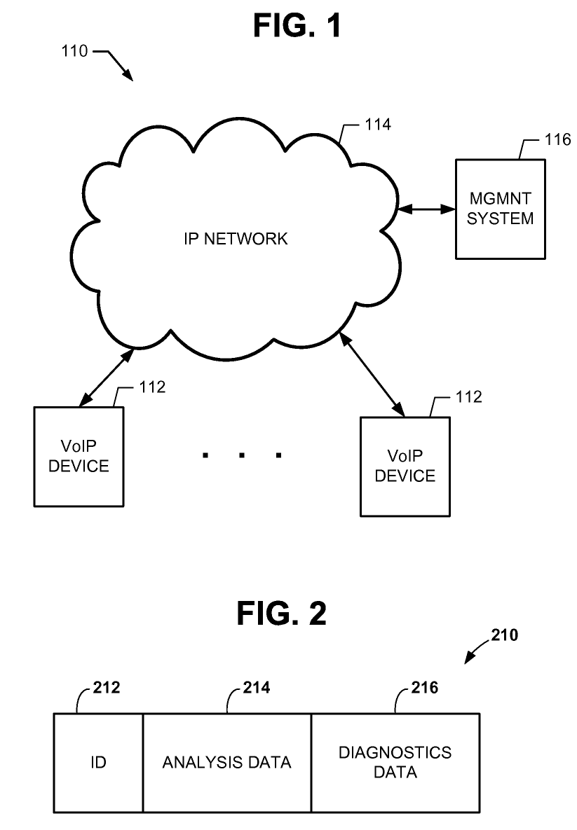

Reference is made to FIG. 1, which illustrates a VoIP system 110 including a plurality of different VoIP-aware devices 112 that communicate over an IP network 114. The network 114 can be wired, or wireless, or a combination of the two. The devices 112 are VoIP-aware because they can handle VoIP traffic (e.g., audio packets). Most, if not all of the VoIP-aware devices 112 can handle bi-directional traffic in that they can receive and send VoIP traffic. VoIP devices 112 include, without limitation, IP phones, soft clients, dual mode phones, set top boxes, gateways, session border controllers (e.g., firewalls), CPE, conference units, and other wireline and wireless devices that generate or terminate VoIP traffic.

A VoIP call involves at least two VoIP-aware devices 112. During a typical VoIP call, a stream of audio packets flows between two VoIP-aware devices 112, as each VoIP-aware device 112 sends and receives audio packets (two unidirectional audio streams form a call). For each direction, one VoIP-aware device 112 (the “sending device”) sends packets to the other VoIP-aware device 112 (the “receiving” device).

Other VoIP-aware devices 112 might be involved with the call. For example, a VoIP-aware device 112 such as a gateway might handle the streams. The gateway can also handle streams for other VoIP calls. For instance, carrier grade gateways can handle hundreds of calls in parallel.

Each VoIP-aware device 112 has diagnostics capability, which allows it to generate its own diagnostics data. The diagnostics data identifies problems about any of implementation, configuration, and utilization of the sending device and the network 114. Each VoIP-aware device 112 can generate certain diagnostics data from differences in receipt times of consecutive packets of the same audio stream (consecutive packets may be identified by consecutive sequence numbers). Such data is generated in real time from real VoIP traffic.

The diagnostics data may be generated as follows. Packets are received, Interarrival times are generated, the Interarrival times are aggregated (e.g., histograms are formed), and the diagnostics data is generated from the aggregated Interarrival times (e.g., pattern recognition is performed on the histograms to identify problems that affect VoIP voice quality). This approach is described in greater detail in applicant's U.S. Ser. No. ______ (attorney docket number Vdc-101 entitled “VoIP Diagnosis”), filed herewith and incorporated herein by reference.

These VoIP-aware devices 112 do not require artificial VoIP traffic or sender time stamps to generate such diagnostics data. When a problem is diagnosed by a VoIP-aware device 112, the VoIP-aware device 112 transmits its diagnostics data to a management system 116. The diagnostics data may be transmitted in the form of a diagnostics data structure (described below).

Diagnostics data could be transmitted synchronously instead of asynchronously. For example, diagnostics data could be transmitted every five seconds instead of when a problem occurs. However, the synchronous transmission increases traffic, and increases the amount of data that the management system 116 has to process.

The real VoIP traffic may include RTP packets or other packets that follow a standard. Or, the real VoIP traffic may include audio packets that follow a proprietary protocol.

Reference is now made to FIG. 2, which illustrates an exemplary diagnostics data structure 210. The data structure 210 may have the following format: a first field 212 containing identification data, a second field 214 containing analysis data, and a third field 216 containing diagnostics data. The function of the identification data is to identify the VoIP-aware devices involved in an audio stream (the VoIP device-aware that has generated the audio stream and the VoIP-aware device that has received and diagnosed the audio stream). Although a data structure 210 having three fields is shown, a data structure according to an embodiment of the present invention may have a different number of fields or no fields at all.

Moreover, a data structure is not required to contain each of ID data, analysis data and diagnostics data. Some embodiments of the data structure might not contain analysis data.

Returning to FIG. 1, the management system 116 can perform diagnostics and troubleshoot voice quality problems, including localizing problems that degrade VoIP voice quality. For example, the management system 116 receives the diagnostics data structures from the VoIP-aware devices 112. The management system 116 may itself generate diagnostics data from traffic on the VoIP system 110.

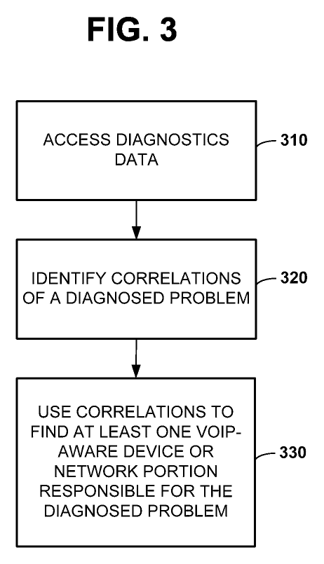

Reference is now made to FIG. 3, which illustrates a method of using diagnostics data structures from different VoIP-aware devices to localize a cause of a problem that degrades VoIP voice quality. At block 310, diagnostics data is accessed from VoIP-aware devices in the IP network (block 310). This may be performed by receiving the diagnostics data structures via the network, and reading the diagnostics data in the different data structures.

The diagnostics data indicates problems that cause degradation in VoIP voice quality. These problems could include any of implementation, configuration, and utilization problems of the sender and/or the network.

At block 320, correlations of a diagnosed problem are identified. As used herein, a correlation involves determining whether any calls experienced the same kind of problem (e.g. network utilization) at the same time. The calls being correlated may include all calls of the IP network or just a portion thereof. The portion (subset) may be determined by specific parameters. Exemplary parameters include, without limitation, endpoints, groups of endpoints, sender-receiver combinations, traffic type (uncompressed voice, or compressed voice and codec used), time, topology, etc. For example, a correlation could involve checking for a network utilization problem at the same time for a specific group of endpoints that are situated in a specific building.

At block 330, the correlations are used to find a network portion responsible for the diagnosed problem. Granularity of a network portion can be as fine as one or more network components. Consider an example of a database that contains all diagnostic information from all calls by VoIP-aware devices nationwide (e.g., in the United States). A database query may ask for all calls that have shown degradation due to network utilization problems. If such calls are equally distributed all over North America, the problem is more or less a general problem. However, if all calls with the network utilization problems happen when placed from New York City, then the problem has been localized to a portion of the network near or in New York City. By increasing the granularity of such database queries, the granularity of the network portion is increased.

The correlations can reveal causes other than just network portions. The correlations can also reveal VoIP-aware devices. For instance, if a correlation doesn't show any coinciding problems in the network (if all problems seem to be isolated), yet problems still occur, then it can be assumed that the problems occur in different network portions or even in specific endpoints (VoIP-aware devices).

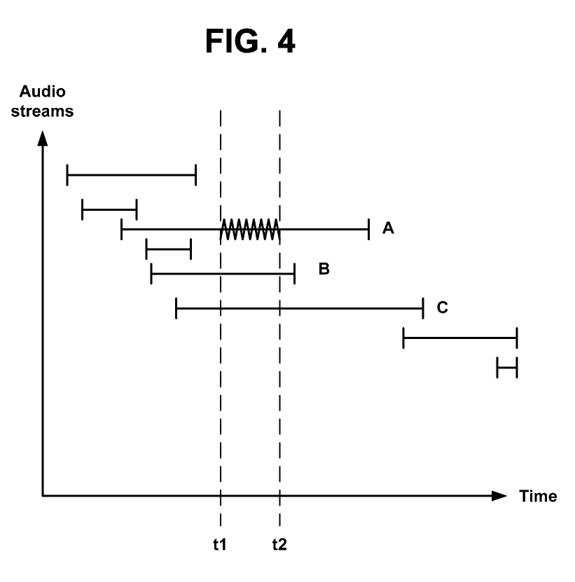

Reference is now made to FIG. 4, which shows a timeline of different audio streams. The audio streams might contain specific problems. Each timeline corresponds to an audio stream, showing its start, duration and end. As shown in FIG. 4, audio streams A, B and C have an overlap in time. Audio stream A shows a specific problem between times t1 and t2. Performing the function at block 320 would reveal that audio streams B and C have the same problem at the same period of time (between t1 and t2). Thus, calls A, B and C have been correlated.

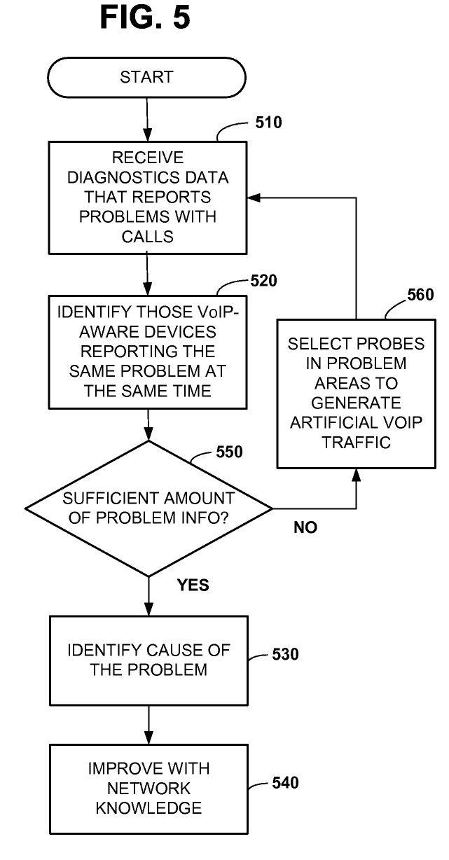

FIG. 5 illustrates a method of identifying correlations and locating problems that cause degradation in VoIP voice quality. At block 510, diagnostics data is received. The diagnostics data reports problems with calls. The diagnostics data may be contained in diagnostics data structures.

At block 520, those VoIP-aware devices reporting the same problem at the same time are identified. For instance, the management system could keep records (e.g., a database) of VoIP-aware devices, problems, and times that the problems occurred. Synchronously (i.e., periodically) or asynchronously (e.g., when a problem occurs), the management system searches the records for those VoIP-aware devices reporting the same problem at the same time. If a database query is performed, the database query can ask for all problems or it can be a selected query, just looking for one or more parameters. Exemplary selected queries could look for calls with network utilization problems, for those calls having multiple problems at the same time, for all calls having problems over an interval (e.g., in a five second interval), and so on.

Consider an IP network including a plurality of VoIP-aware devices, where each VoIP-aware device delivers diagnostics data every T seconds (e.g., T=5). Every call can be described by a specific number of such subsequent diagnostics corresponding to the length of the call. Correlation now refers to every data structure (representing the T seconds of diagnostics data) that provides information about potential problems and if so, in more depth diagnosis information about the cause of the problem. Based on these T second intervals, the database can be scanned for other diagnostics data showing the same problems at the same time. The interval of T=5 seconds offers a reasonable compromise between accuracy of diagnosis information and amount of diagnosis data needed. However, intervals other than T=5 seconds may be used.

At block 530, a cause of the degradation problem is identified. The correlated VoIP-aware devices, their relation to the IP network, and the nature of the indicated problem are examined. For example, IP addresses of correlated VoIP-aware devices are examined. From this and the nature of the problem, the problem can be identified. Thus, the problem can be identified without any knowledge of how the network is structured.

Consider the following examples. As a first example of a correlation, a specific endpoint indicates that it has a specific problem with a call. Other endpoints are searched to determine whether the other endpoints have the same problem at the same time.

As a second example of a correlation, a search is performed to see whether a particular problem occurs for just one pair of sending-receiving devices or whether the problem occurs for multiple senders and just one receiver that use the same portion of a network infrastructure. In the case of multiple sending devices and just one receiver, the problem is more likely to be located near the receiving device, because the receiving device has the same problem, regardless which one of the multiple sending devices is involved and regardless of where they are located.

As a third example of a correlation, a search is performed to determine whether a group of IP addresses experience the same problem. Problems at specific IP addresses could be identified. For instance, it might be known that ten VoIP-aware devices are connected to switch no. 12 in a certain building. If these devices all have the same problem, then switch no. 12 can be isolated as the source of the problem.

As a fourth example of a correlation, a search is performed to find all disturbed compressed calls that use a particular compression codec (e.g. G.729), that show network related problems from this morning between 9 am and 10 am, and that have been generated by endpoint group xyz and sent to endpoint abc.

Each of these four examples involves a search. A search could be performed manually, by looking at appropriate graphs, or automatically making queries of a database, etc.

At block 540, knowledge about the network can be used to narrow the cause of the degradation problem. That is, knowledge about the network can be used to pinpoint the cause of the problem, perhaps down to one or more components of a network. Such knowledge could include information about the network components to which VoIP devices are connected.

The network knowledge might be found in a network diagram. The correlations may be mapped against a network diagram. Endpoints (VoIP-aware devices) can be characterized by the network components to which they are physically connected and to the logical portions (e.g., virtual LAN) to which they belong. In addition, endpoints can be grouped (e.g., to describe a remote site or a building).

The network knowledge might be provided by location-aware VoIP-aware devices that generate at least some of the traffic. These VoIP-aware devices may provide GPS data, cell data (GSM), access point data (WLAN), etc. Using locations provided by these devices, problems can be further localized. Consider a cell phone that can move from one cell area to another. If the cell phone experiences a problem with VoIP voice quality, a management system can search for other such VoIP-aware devices in the same cell area and investigate whether those other devices also experienced any of or exactly the same problems.

Performing the diagnostic analysis might require a minimum amount of information about voice quality problems in real VoIP traffic. If a network problem has been diagnosed, but the amount of information from real VoIP traffic is insufficient to perform a reasonable correlation (block 550), then artificial VoIP traffic can be selectively generated (block 560). Artificial VoIP calls can be temporarily made to a specific network area that shows problems, but where not enough real VoIP calls have been placed to localize the problem.

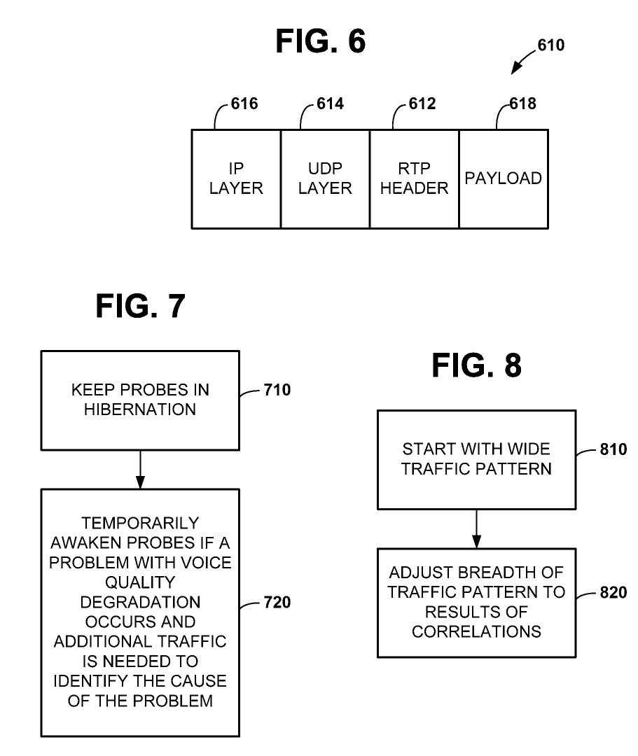

Reference is made to FIG. 6. The artificial VoIP traffic may include RTP packets that include an RTP header 612 (which includes a sequence number), a UDP header 614, and an IP layer 616. Each packet 610 includes additional information, such as a MAC layer for wired networks and an 802.11 layer for wireless networks. Both the MAC layer and the 802.11 layer are in front of the IP layer 218. Under ideal conditions, these packets 610 are sent and received isochronously (e.g., every 20 milliseconds). Packets 610 for artificial VoIP traffic include a payload 618, but the payload 618 does not contain real voice data. Rather, all bytes of the payload 618 may be set to zero or may be used to carry other data.

The artificial VoIP traffic may be generated and processed by a subset of VoIP-aware devices called “probes.” A probe may have a physical interface that allows a connection to an IP network, a TCP/IP protocol stack for communicating with other IP devices, and a VoIP protocol stack (e.g., an RTP protocol stack) in order to send and receive VoIP calls. The probe also has diagnostics capability as described above. The probes can generate artificial VoIP traffic, they can receive artificial VoIP traffic from other probes, they can generate diagnostics data from the artificial VoIP traffic, and they can send the diagnostics data to the management system.

Probes are deployed at preferred and strategic locations in a VoIP system. Consider the example of a company with 1000 IP phones at its headquarters and another five to ten IP phones at each of its ten branch offices. The ten branch offices may be considered strategic locations because they represent the physical structure of a network (the branches are at different physical locations than the headquarters). The headquarters, with its 1000 IP phones, is subdivided into five different virtual LANs. The virtual LANs, even though at the same physical location, represent independent logical instances of the network. Therefore, each of the virtual LANs may also be considered as a strategic location.

These preferred and strategic locations may represent the topology of the network, or the physical structure of the network, or the logical structure of the network, or any combination thereof. Further to the example just provided, the virtual VLANs at the headquarters have a similar size (200 IP phones each). Usually networks (or portions of networks) of 200 and more devices are further subdivided and segmented. To localize problems with the highest accuracy, there should be more than 1-2 probes per segment (virtual LAN in this example). If the number of probes is increased further to have at least one probe per segment of each virtual LAN, a specific segment of that virtual LAN could be localized.

A diagram may be used in combination with the probes to identify the preferred and strategic locations. A topographic map may represent the topographic structure of the IP network. To resolve physical and logical structure, a network diagram (physical connections and logical configurations) may be used.

The probes are controlled by a management system (e.g., the management system 116 of FIG. 1). The breadth of a call pattern by the probes is a function of selection and distribution of probes involved, the destination to be called, time of calls, amount of calls, duration of calls, characteristic of calls (e.g., the Codec used), sample rate used, etc.

The management system can use the diagnostics data structures from both artificial and real traffic to localize the cause of a problem. However, the management system is not so limited, as it could use only the data structures generated from artificial VoIP traffic.

Reference is made to FIG. 7, which illustrates an example of how a management system controls the probes The probes are normally kept in hibernation so as not to increase VoIP traffic (block 710), but are awakened temporarily by a management system if a problem with voice quality degradation occurs and additional traffic is needed to identify the cause of the problem (block 720). Once awoken, the probes deliver additional diagnostics data in order to locate the cause of the degradation. In some embodiments, the trigger event for the management system to wake up probes is the presence of problems with the VoIP voice quality in absence of a sufficient amount of real VoIP traffic to perform a correlation. The resulting correlation is based on diagnostics data from real VoIP traffic and artificial VoIP traffic.

Reference is now made to FIG. 8, which illustrates a method of searching for the cause of a VoIP voice degradation problem. At block 810, the probes start with a wide call pattern. At block 820, the breadth of the call pattern is adjusted to the results of the correlation. For example, a set of hibernating probes are initially activated to generate artificial VoIP traffic in the United States, and the cause of a diagnosed problem is localized to New York City. Next, only those probes in Manhattan are used to generate artificial VoIP traffic (all other probes are placed back in hibernation). If the diagnosed problem is not found, the probes in Manhattan are placed back in hibernation and probes for another borough are awoken. If the diagnosed problem is pinpointed to Manhattan, only those probes near a specific section (e.g., Broadway) are used to generate traffic. If the diagnosed problem is pinpointed to Broadway, the call pattern can be narrowed even further.

The correlation analysis is not limited to artificial VoIP traffic in conjunction with real traffic. As indicated above, correlation analysis could be based exclusively on artificial VoIP traffic.

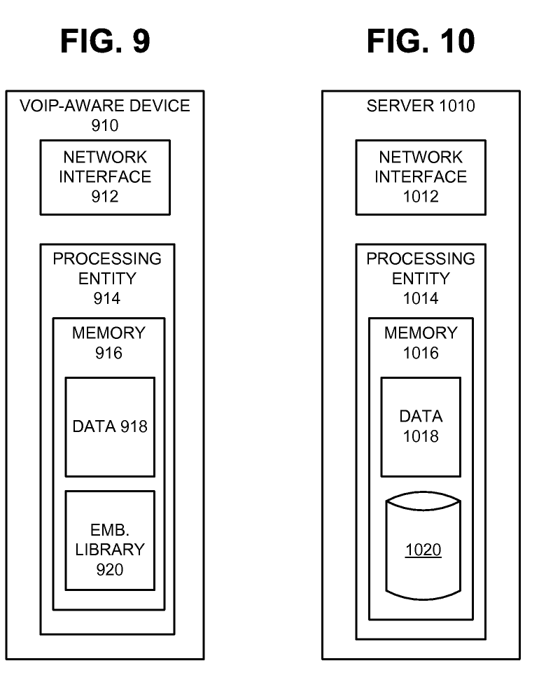

Reference is now made to FIG. 9, which illustrates an example of a VoIP-aware device 910. The VoIP-aware device 910 includes a network interface 912, and a processing entity 914. The processing entity 914 is programmed to run a TCP/IP protocol stack for communicating with other IP devices, and a VoIP protocol stack (e.g., an RTP protocol stack) for communicating with other VoIP-aware devices. The processing entity 914 may include a digital signal processor and firmware. The processing entity 914 may include memory 916 encoded with data 918 for programming the device 910. The memory 916 may also be encoded with an embedded library 920 or other data for generating the diagnostics data and the data structures from either real traffic or artificial VoIP traffic.

FIG. 10 is an illustration of a server 1010 for a management system. Although only a single server 1010 is shown in FIG. 10, it is understood that the management system may include multiple servers.

The management system server 1010 may include a physical interface 1012 that allows a connection to an IP network. The server 1010 also includes a processing entity 1014 that runs a TCP/IP protocol stack for communicating with other IP devices. The server 1010 may be programmed to access diagnostics data, identify correlations, and identify causes of diagnosed problems. The server 1010 may be programmed to manage the probes. The processing entity 1014 may include memory 1016 encoded with data 1018 for programming the server 1010. The memory 1016 may also store a database 1020 of problems diagnosed by VoIP-aware devices and probes. Some parts of the server 1010, such as its database 1020, may be physically separate entities.

1. A method comprising:
accessing diagnostics data from VoIP devices in an IP network, the diagnostics data indicating problems that cause degradation in VoIP voice quality;
using the diagnostics data to identify correlations of a diagnosed problem; and
using the correlations to localize a cause of the diagnosed problem.

2. The method of claim 1, wherein the diagnostics data is accessed from diagnostics data structures generated by the VoIP-aware devices.

3. The method of claim 1, wherein accessing the diagnostics data includes receiving packets, generating Interarrival times for consecutive packets; aggregating the Interarrival times; and generating the diagnostics data from the aggregated Interarrival times.

4. The method of claim 1, wherein identifying the correlations includes identifying those VoIP-aware devices reporting the same problem at the same time.

5. The method of claim 1, wherein using the correlations includes looking at the correlated devices and the nature of the diagnosed problem to localize a cause of the diagnosed problem.

6. The method of claim 5, further comprising using knowledge about the network to further localize the diagnosed problem.

7. The method of claim 6, wherein using the network knowledge includes mapping the correlations against a network diagram.

8. The method of claim 6, wherein at least some of the VoIP-aware devices are also location-aware; and wherein using the network knowledge includes using the correlations with locations provided by the location-aware devices.

9. The method of claim 1, wherein the diagnostics data used for the correlations is generated at least in part from real VoIP traffic.

10. The method of claim 1, wherein the diagnostics data used for the correlations is generated from real VoIP traffic in combination with artificial VoIP traffic.

11. The method of claim 1, wherein the diagnostics data used for the correlations is generated exclusively from artificial VoIP traffic.

12. The method of claim 1, further comprising using probes to temporarily generate the artificial VoIP traffic if a problem with voice quality degradation occurs and additional traffic is needed to localize a cause of the diagnosed problem.

13. The method of claim 12, wherein the probes are normally in hibernation so as not to increase VoIP traffic, but are awakened if needed to generate the additional traffic.

14. The method of claim 12, wherein breadth of a call pattern by the probes is adjusted to the results of the correlation.

15. A system comprising at least one server for performing the method of claim 1.

16. An article comprising memory encoded with data for causing a server to perform the method of claim 1.

17. Apparatus comprising:
means for accessing diagnostics data from VoIP-aware devices in an IP network, the diagnostics data indicating problems that cause degradation in VoIP voice quality;
means for identifying correlations of a diagnosed problem; and
means for using the correlations to find at least one VoIP device or network portion responsible for the diagnosed problem.

18. A system comprising at least one server for accessing diagnostics data from VoIP-aware devices in an IP network; identifying correlations of a diagnosed problem; and using the correlations to localize a cause of the diagnosed problem

19. An article for a server, the article comprising memory encoded with data for causing the server to access diagnostics data from VoIP-aware devices; identify correlations of a diagnosed problem; and use the correlations to find at least one VoIP-aware device or network portion responsible for the diagnosed problem.

20. The article of claim 19, wherein the memory further stores a database of different VoIP-aware device problems that can affect VoIP voice quality.
